(19) United States
(12) Patent Application Publication
(10) Pub. No.: US 2026/0173686 A1
(43) Pub. Date: Jun. 18, 2026

(54) Display Device and Method of Manufacturing the Same

(71) Applicant: LG Display Co., Ltd., Seoul (KR)

(72) Inventor: Yeoun Jei Jung, Paju-si (KR)

(21) Appl. No.: 19/358,342

(22) Filed: Oct. 14, 2025

(30) Foreign Application Priority Data
Dec. 13, 2024 (KR) 10-2024-0186225

(51) Int. Cl. H10K 59/131; H10K 59/12; H10K 102/00

(52) U.S. Cl. CPC H10K 59/131; H10K 59/1201; H10K 2102/311

(57) ABSTRACT

A display device and a method of manufacturing the same are disclosed. The display device includes a display panel including an active area configured to display an image, an extension part extending from a substrate included in the display panel, a bending area included in the extension part and configured to be bent to allow the extension part to be disposed at a back side of the display panel, a pad area included in the extension part and configured to facilitate connection to an external circuit board, a line area disposed in the pad area, the bending area, and the active area, the line area including lines configured to a signal and a voltage applied through the pad area, and a dummy area positioned adjacent to the bending area and disposed outside the line area.

### CROSS-REFERENCE TO RELATED APPLICATIONS

This application claims the benefit of Korean Patent Application No. 10-2024-0186225, filed on Dec. 13, 2024, which is hereby incorporated by reference as if fully set forth herein.

### BACKGROUND OF THE DISCLOSURE

### Field of the Disclosure

The present disclosure relates to a display device and a method of manufacturing the same.

### Discussion of the Related Art

In accordance with advances in information technology, the market for display devices, which are connection media between users and information, is expanding. Accordingly, use of display devices such as light emitting display (LED) devices, quantum dot display (QDD) devices, liquid crystal display (LCD) devices, etc. is increasing.

The above-mentioned display devices include a display panel including sub-pixels, a driver configured to output a drive signal for driving of the display panel, a power supply configured to generate power to be supplied to the display panel or the driver, etc.

In such display devices, when a drive signal, for example, a scan signal, a data signal, or the like, is supplied to sub-pixels formed at the display panel, selected ones of the sub-pixels transmit light therethrough or directly emit light and, as such, an image may be displayed.

### SUMMARY OF THE DISCLOSURE

Accordingly, the present disclosure is directed to a display device and a method of manufacturing the same that substantially obviate one or more problems due to limitations and disadvantages of the related art.

The present disclosure aims to prevent a resin, which is used in a display module having a configuration in which an extension part of a display panel is bent to be folded toward a back side of the display panel, from penetrating a gap space formed at the extension part of the display panel. Additionally, the present disclosure aims to minimize a problem (for example, line cracks) possibly occurring due to thermal deformation of the resin and the resulting stress when penetration of the resin has occurred. Additionally, the present disclosure aims to not only enhance electrical and structural stability and reliability of the resultant device, but also to increase the lifespan of the device by preventing or minimizing introduction of foreign matter or moisture into the gap space formed at the extension part of the display panel.

In one aspect of the present disclosure, a display device includes a display panel including an active area configured to display an image, an extension part extending from a substrate included in the display panel, a bending area included in the extension part and configured to be bent to allow the extension part to be disposed at a back side of the display panel, a pad area included in the extension part and configured to facilitate connection to an external circuit board, a line area disposed in the pad area, the bending area, and the active area, the line area including lines configured to transmit a signal and a voltage applied through the pad area, and a dummy area positioned adjacent to the bending area and disposed outside the line area.

The dummy area may be locally disposed adjacent to outer edges of the extension part.

The extension part may have a state of being bent based on a structure such that the extension part is disposed at the back side of the display panel and has a gap space formed between the bending area and the structure.

The extension part may include a trimming line area defined to allow for a trimming process to be performed therein and disposed outside the dummy area. The trimming line area and the dummy area may have different interlayer structures, respectively.

The trimming line area and the dummy area may include at least one organic layer in common.

The at least one organic layer may be separated by an organic layer disconnection part disposed between the trimming line area and the dummy area.

The dummy area and the line area may commonly include the substrate disposed at the extension part, a first planarization layer disposed on the substrate, a second planarization layer disposed on the first planarization layer, and a pixel defining layer disposed on the second planarization layer.

The trimming line area may have a lower interlayer structure than the dummy area.

The trimming line area may include the first planarization layer disposed on the substrate.

The trimming line area may further include an inorganic layer extending from the dummy area disposed between the first planarization layer and the substrate.

In another aspect of the present disclosure, a method of manufacturing a display device includes attaching a circuit board to the pad area included in the extension part of the display panel described above, bending the bending area to allow the extension part including the pad area, the line area, and the dummy area to be disposed at the back side of the display panel, and coating the bending area and a surrounding area thereof with a resin.

The dummy area may be locally disposed adjacent to outer edges of the extension part.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a block diagram schematically showing a display device;

FIG. 2 is a block diagram showing a configuration of a gate driver in the display device;

FIG. 3 is a cross-sectional view showing a stacked structure of a display panel in the display device;

FIG. 4 is an illustrative front view of a display module including the display panel;

FIG. 5 is an illustrative rear view of the display module including the display panel;

FIG. 6 is an illustrative view showing a state in which a printed circuit board is attached to a back side of the display panel through bending as shown in FIG. 5;

FIG. 7 is a plan view showing a configuration included in the display panel in more detail;

FIG. 8 is an illustrative view showing a first example of a state in which a bending area is bent toward the back side of the display panel in FIG. 7, and a configuration of the bending area in more detail;

FIG. 9 is an illustrative view showing a second example of a state in which a bending area is bent toward the back side of the display panel in FIG. 7, and a configuration of the bending area in more detail;

FIG. 10 is an illustrative cross-sectional view showing an A1-A2 area before application of resin in FIGS. 8 and 9;

FIG. 11 is an illustrative cross-sectional view of the A1-A2 area after application of resin in FIGS. 8 and 9;

FIG. 12 is an illustrative view showing an extension part of the display panel shown in FIG. 8;

FIG. 13 is a cross-sectional view showing an area PP shown in FIG. 12 in accordance with a first embodiment;

FIG. 14 is a cross-sectional view showing the area PP shown in FIG. 12 in accordance with a second embodiment; and

FIG. 15 is a cross-sectional view showing the area PP shown in FIG. 12 in accordance with a third embodiment.

### DETAILED DESCRIPTION OF THE DISCLOSURE

The display device according to the present disclosure may be embodied as a light emitting display (LED) device, a quantum dot display (QDD) device, etc. For convenience of description, however, the following description will be given in conjunction with an example in which the display device according to the present disclosure is a light emitting display device configured to directly emit light based on an inorganic light emitting diode or an organic light emitting diode.

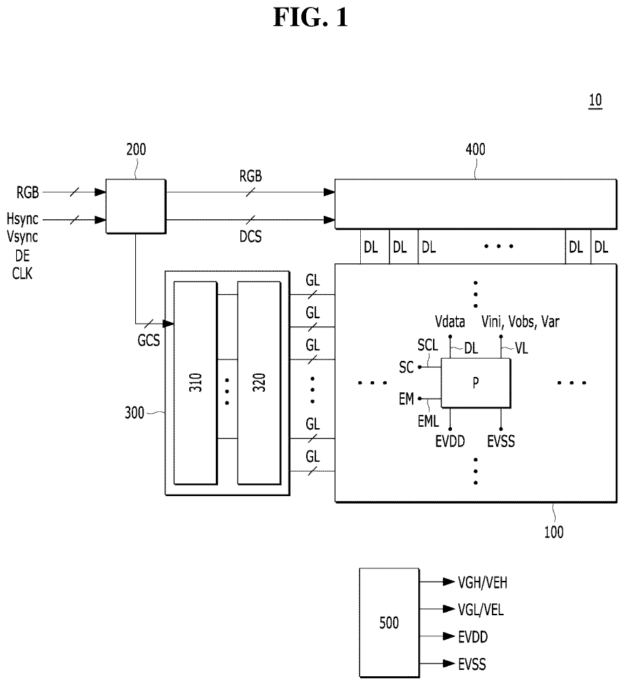

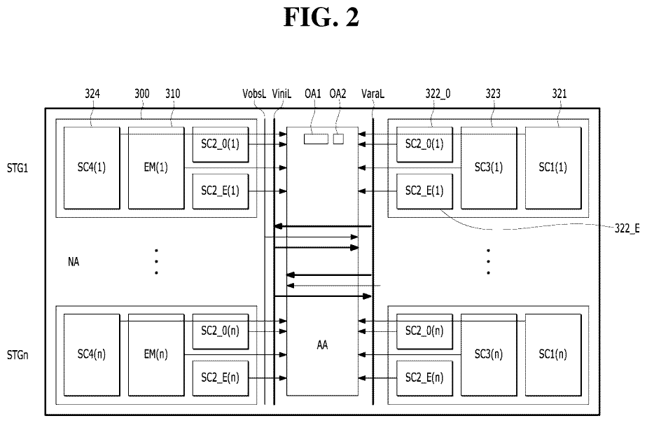

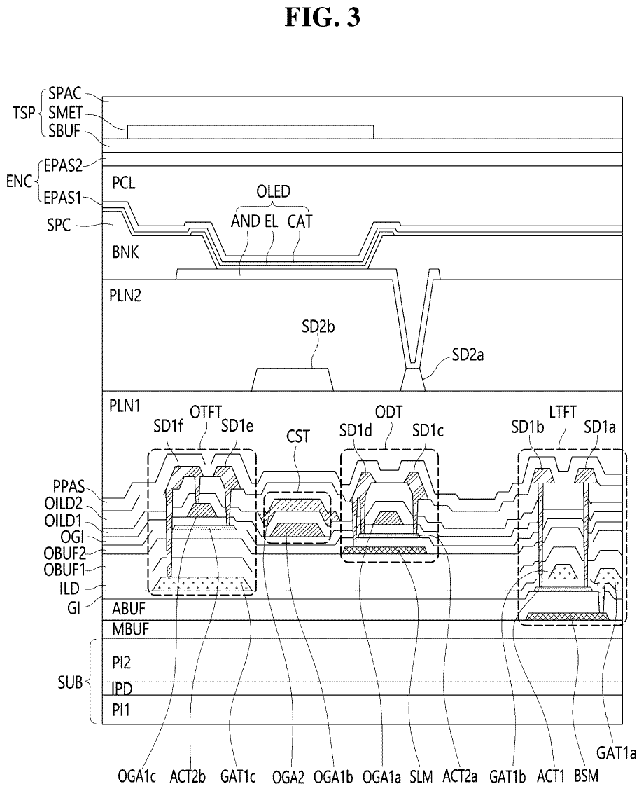

FIG. 1 is a block diagram schematically showing a display device. FIG. 2 is a block diagram showing a configuration of a gate driver in the display device. FIG. 3 is a cross-sectional view showing a stacked structure of a display panel in the display device.

As shown in FIG. 1, the display device, which is designated by reference numeral “10”, may include a display panel 100 including a plurality of sub-pixels P, a controller 200, a gate driver 300 configured to supply a gate signal to the plurality of sub-pixels P, a data driver 400 configured to supply a data signal (or a data voltage) to the plurality of sub-pixels P, a power supply 500 configured to supply power to the plurality of sub-pixels P, etc.

The display panel 100 may include an active area AA (see FIG. 2) in which the plurality of sub-pixels P is disposed, and a non-active area NA (see FIG. 2) disposed to surround the active area AA. The gate driver 300 and the data driver 440 may be disposed in the non-active area NA.

At the display panel 100, a plurality of gate lines GL and a plurality of data lines DL may intersect each other. The plurality of sub-pixels P may be connected to respective gate lines GL and respective data lines DL. In detail, each sub-pixel P may receive a gate signal from the gate driver 300 through a corresponding one of the gate lines GL, may receive a data voltage (a data signal) from the data driver 400 through a corresponding one of the data lines DL, and may receive a high-level voltage EVDD and a low-level voltage EVSS from the power supply 500.

Respective gate lines GL may transmit a scan signal SC and an emission control signal EM to the plurality of sub-pixels P, and respective data lines DL may transmit a data voltage Vdata to the plurality of pixels P. In accordance with various embodiments, respective gate lines GL may include a plurality of scan lines SCL for supply of the scan signal SC, and a plurality of emission control signal lines EML for supply of the emission control signal EM. The plurality of pixels P may each receive voltages Vini, Var, and Vobs through a plurality of voltage lines VL. The voltages Vini, Var, and Vobs applied through the plurality of voltage lines VL will be described later.

The plurality of sub-pixels P may each include a sub-pixel driving circuit. The sub-pixel driving circuit may include a plurality of switching elements, a driving element, a capacitor, etc. The switching elements, the driving element, etc. may each be constituted by a thin film transistor. Each of the switching elements may be switched in accordance with a scan signal SC supplied thereto through a corresponding one of the scan lines SCL and an emission control signal EM supplied thereto through a corresponding one of the emission control lines EML. The driving element may adjust an amount of current supplied to a light emitting element OLED (luminous amount) in accordance with a data voltage Vdata.

The display panel 100 may be implemented as a non-transmissive display panel or a transmissive display panel. The transmissive display panel may be applied to a transparent display device in which an image is displayed on a screen and through which an actual background is visible. The display panel 100 may be implemented as a flexible display panel. For the flexible display panel, a plastic substrate may be employed. The plurality of sub-pixels P may each be divided into a red sub-pixel, a green sub-pixel, and a blue sub-pixel. The plurality of sub-pixels P may each further include a white sub-pixel.

Touch sensors may be disposed on the display panel 100. Touch input may be sensed using separate touch sensors or may be sensed through the plurality of sub-pixels P. The touch sensors may be disposed on a screen of the display panel 100 in an on-cell type or an add-on type or may be implemented as in-cell type touch sensors built in the display panel 100.

The controller 200 may process image data RGB input thereto from an outside thereof, to match the size and resolution of the display panel 100, and may then supply the processed image data RGB to the data driver 400. The controller 200 may generate a gate control signal GCS and a data control signal DCS using synchronization signals input from the outside thereof, for example, a dot clock signal CLK, a date enable signal DE, a horizontal synchronization signal Hsync, and a vertical synchronization signal Vsync. The controller 200 supplies the gate control signal GCS to the gate driver 300 to control an operation timing of the gate driver 300. The controller 200 may supply the data control signal DCS to the data driver 400 to control an operation timing of the data driver 400. The controller 200 may synchronize operation timings of the gate driver 300 and the data driver 400 using the gate control signal GCS and the data control signal DCS.

The controller 200 may be configured to be coupled with various processors, for example, a microprocessor, a mobile processor, an application processor, etc. in accordance with a device mounted therein. A host system, which is disposed at an upstream stage of the controller 200, may be one of a television (TV) system, a set-top box, a navigation system, a personal computer (PC), a home theater system, a mobile appliance, a wearable appliance, and a vehicle system.

The controller 200 may multiply an input frame frequency by i times to control the operation timings of the display panel drivers at a frame frequency corresponding to an “input frame frequency×i” Hz (i being a positive integer greater than 0). The input frame frequency may be 60 Hz in a national television standards committee (NTSC) system, and may be 50 Hz in a phase-alternating line (PAL) system.

The controller 200 may drive the display panel 100 at various refresh rates. The controller 200 may drive the display panel 100 in a variable refresh rate (VRR) mode, in other words, to be switched between a first refresh rate and a second refresh rate.

For example, the controller 200 may drive the display panel 100 at various refresh rates by simply varying a rate of a clock signal, configuring a synchronization signal, for generation of a horizontal blank or a vertical blank, or driving the gate driver 300 in a mask manner. The vertical blank may be defined as a period for matching input timing of a data signal and output (display) timing of an image to the display panel 100. The vertical blank may be repeated at intervals of one frame and may synchronize various signals for operation of the display device in each frame period.

The voltage level of the gate control signal GCS output from the controller 200 may be converted into a gate-on voltage VGL/VEL and a gate-off voltage VGH/VEH through a level shifter not shown, and the gate-on voltage VGL/VEL and the gate-off voltage VGH/VEH may then be supplied to the gate driver 300. The level shifter may convert a low-level voltage of the gate control signal GCS into a gate-low voltage VGL, and may convert a high-level voltage of the gate control signal GCS into a gate-high voltage VGH. The gate control signal GCS may include a start pulse, a shift clock, etc.

The gate driver 300 may supply a gate signal to each gate line GL in accordance with a gate control signal supplied from the controller 200. The gate driver 300 may be disposed at one side or both sides of the display panel 100 in a gate-in-panel (GIP) manner.

The gate driver 300 may sequentially output a gate signal to a plurality of gate lines GL under control of the controller 200. The gate driver 300 may shift the gate signal using a shift register and, as such, may sequentially supply shifted gate signals to the gate lines GL, respectively.

The gate signal may include a scan signal SC and an emission control signal EM in an organic light emitting display device. The scan signal SC may include a scan pulse swing between a gate-on voltage VGL and a gate-off voltage VGH. The emission control signal EM may include an emission control signal pulse swing between a gate-on voltage VEL and a gate-off voltage VEH. The scan pulse may select sub-pixels P of a line to which a data voltage Vdata will be written. The emission control signal EM may define an emission time of the sub-pixels P.

The gate driver 300 may include an emission control signal driver 310 and at least one scan driver 320. The emission control signal driver 310 may output an emission control signal pulse in response to a start pulse and a shift clock from the controller 200, and may sequentially shift the emission control signal pulse in accordance with the shift clock. The at least one scan driver 320 may output a scan pulse in response to the start pulse and the shift clock from the controller 200, and may shift the scan pulse in accordance with a timing of the shift clock.

The data driver 400 may convert image data RGB into a data voltage Vdata in accordance with a data control signal DCS supplied from the controller 200, and may output the data voltage Vdata through the data lines DL.

Although the data driver 400 is shown in FIG. 1 as being disposed in the form of a single data driver at one side of the display panel 100, the number and position thereof are not limited to those shown in FIG. 1. That is, the data driver 400 may be constituted by a plurality of integrated circuits (ICs) and, as such, may be disposed at one side of the display panel 100 in a state of being divided into portions respectively corresponding to the plurality of ICs.

The power supply 500 may generate DC power required for driving of the sub-pixel array and the display panel drivers of the display panel 100, using a DC-DC converter. The DC-DC converter may include a charge pump, a regulator, a buck converter, a boost converter, etc. The power supply 500 may receive a DC input voltage applied from a host system (not shown), thereby generating DC voltages such as a gate-on voltage VGL/VEL, a gate-off voltage VGH/VEH, a high-level voltage EVDD, a low-level voltage EVSS, etc. The gate-on voltage VGL/VEL and the gate-off voltage VGH/VEH may be supplied to the level shifter (not shown) and the gate driver 300. The high-level voltage EVDD and the low-level voltage EVSS may be supplied to the plurality of sub-pixels P in common.

As shown in FIGS. 1 and 2, the gate driver 300 may include one emission control signal driver 310 and one scan driver 320. The scan driver 320 may include first to fourth scan drivers 321, 322, 323, and 324. Additionally, the second scan driver 322 may include an odd-numbered second scan driver 322_O and an even-numbered second scan driver 322_E.

The shift register, which constitutes the gate driver 300, may be configured to be symmetrical at both sides of the active area AA. The shift register at one side may include the second scan drivers 322_O and 322_E, the fourth scan driver 324, and the emission control signal driver 310, whereas the shift register at the other side may include the first scan driver 321, the second scan drivers 322_O and 322_E, and the third scan driver 323. In FIG. 2, the odd-numbered second scan driver 322_O and the even-numbered second scan driver 322_E illustrate an example in which odd-numbered sub-pixels and even-numbered sub-pixels share the second scan driver 322. Therefore, the emission control signal driver 310 and the first to fourth scan drivers 321, 322, 323, and 324 may be arranged differently and are not limited to the above-described arrangement.

Stages STG1 to STGn of the shift register may include respective first scan signal generators SC1(1) to SC1(n), respective second scan signal generators SC2_O(1) to SC2_O(n) and SC2_E(1) to SC2_E(n), respective third scan signal generators SC3(1) to SC3(n), respective fourth scan signal generators SC4(1) to SC4(n), and respective emission control signal generators EM(1) to EM(n).

The first scan signal generators SC1(1) to SC1(n) may output first scan signals SC1(1) to SC1(n) through first scan lines SC1 of the display panel 100, respectively. The second scan signal generators SC2(1) to SC2(n) may output second scan signals SC2(1) to SC2(n) through second scan lines SC2 of the display panel 100, respectively. The third scan signal generators SC3(1) to SC3(n) may output third scan signals SC3(1) to SC3(n) through third scan lines SC3 of the display panel 100, respectively. The fourth scan signal generators SC4(1) to SC4(n) may output fourth scan signals SC4(1) to SC4(n) through fourth scan lines SC4 of the display panel 100, respectively. The emission control signal generators EM(1) to EM(n) may output emission control signals EM(1) to EM(n) through emission control lines EM of the display panel 100, respectively.

The first scan signals SC1(1) to SC1(n) may be used as signals to drive A-th transistors (e.g., compensation transistors, etc.) included in the sub-pixel driving circuits. The second scan signals SC2(1) to SC2(n) may be used as signals to drive B-th transistors (e.g., data supply transistors, etc.) included in the sub-pixel driving circuits. The third scan signals SC3(1) to SC3(n) may be used as signals to drive C-th transistors (e.g., bias transistors, etc.) included in the sub-pixel driving circuits. The fourth scan signals SC4(1) to SC4(n) may be used as signals to drive D-th transistors (e.g., initialization transistors, etc.) included in the sub-pixel driving circuits. The emission control signals EM(1) to EM(n) may be used as signals to drive E-th transistors (e.g., emission control transistors, etc.) included in the sub-pixel driving circuits. For example, light emission times of light emitting elements may be varied by controlling the emission control transistors using the emission control signals EM(1) to EM(n), respectively.

Between the gate driving unit 300 and the active area AA, a bias voltage line VobsL for transmitting a bias voltage Vobs, a first initialization voltage line VaraL for transmitting a first initialization voltage Vini, and a second initialization voltage line ViniL for transmitting a second initialization voltage Var may be disposed.

Although the bias voltage line VobsL, the first initialization voltage line VaraL, and the second initialization voltage line ViniL are shown in the drawings as being disposed at one of left and right sides of the active area AA, the lines may be disposed at both sides of the active area AA without being limited to the above-described arrangement. Even when the lines are disposed at one side of the active area AA, the positions thereof are not limited to the left or right side of the active area AA.

Meanwhile, one or more optical areas OA1 and OA2 may be disposed in the active area AA. The optical areas OA1 and OA2 may be disposed to overlap with one or more optical electronic devices, such as capturing devices like cameras (image sensors), detection sensors such as proximity sensors and ambient light sensors, etc.

The optical areas OA1 and OA2 may have a light-transmitting structure formed to ensure a predetermined level of transmittance or more for operation of optical electronic devices. In other words, the number of pixels P per unit area in the optical areas OA1 and OA2 may be less than the number of pixels P per unit area in a general area of the active area AA that excludes the optical areas OA1 and OA2. That is, the resolution of the optical areas OA1 and OA2 may be lower than that of the general area in the active area AA.

The light-transmitting structure in the optical areas OA1 and OA2 may be formed by patterning a cathode in a region where no sub-pixel is disposed. In this case, the patterned cathode may be removed using a laser or a material such as a cathode deposition barrier layer may be used to selectively form a cathode, for patterning of the cathode.

Additionally, the light-transmitting structure in the optical areas OA1 and OA2 may be formed by separating a light emitting element included in a sub-pixel from a sub-pixel driving circuit of the sub-pixel. In other words, the light emitting element of the sub-pixel may be disposed on the optical areas OA1 and OA2, whereas a plurality of transistors constituting the sub-pixel driving circuit may be disposed around the optical areas OA1 and OA2. In this case, the light emitting element and the sub-pixel driving circuit may be electrically interconnected through a transparent metal layer.

As shown in FIG. 3, on a substrate SUB of the display panel, transistors ODT, OTFT, and LTFT, a capacitor CST, etc. configured to drive a light emitting element OLED may be disposed. The transistors ODT, OTFT, and LTFT may include oxide thin-film transistors ODT and OTFT including an oxide semiconductor material, and a polycrystalline thin-film transistor LTFT including a polycrystalline semiconductor material.

The substrate SUB may include a first substrate layer PI1, a second substrate layer IPD, and a third substrate layer PI2. The first substrate layer PI1 and the third substrate layer PI2 may be selected from organic films including polyimide, whereas the second substrate layer IPD, which is disposed between the first substrate layer PI1 and the third substrate layer PI2, may be selected from inorganic films including silicon oxide (SiO2).

A first buffer layer MBUF may be formed on the substrate SUB. The first buffer layer MBUF serves to block moisture, etc. that may penetrate from the outside, and may be configured by stacking a silicon oxide (SiO2) film to form a multilayer structure. A second buffer layer ABUF may also be disposed on the first buffer layer MBUF in order to protect the device from penetration of moisture. The first buffer layer MBUF and the second buffer layer ABUF may be selected from inorganic films. The following description will be given in conjunction with an example in which the second buffer layer ABUF is included.

A lower gate insulating layer GI may be disposed on the second buffer layer ABUF. A lower interlayer insulating layer ILD selected from inorganic films may be disposed on the lower gate insulating layer GI. A first lower buffer layer OBUF1 may be disposed on the lower interlayer insulating layer ILD. A second lower buffer layer OBUF2 may be disposed on the first lower buffer layer OBUF1.

An upper gate insulating layer OGI may be disposed on the second lower buffer layer OBUF2. A first upper interlayer insulating layer OILD1 may be disposed on the upper gate insulating layer OGI. A second upper interlayer insulating layer OILD2 may be disposed on the first upper interlayer insulating layer OILD1. An upper protective layer PPAS may be disposed on the second upper interlayer insulating layer OILD2.

The polycrystalline thin-film transistor LTFT may include a first active layer ACT1, a 1A-th gate electrode layer GAT1a, a 1B-th gate electrode layer GAT1b, a 1A-th electrode layer SD1a, and a 1B-th electrode layer SD1b, which are disposed between the second buffer layer ABUF and the upper protective layer PPAS. The polycrystalline thin-film transistor LTFT may further include a first shield layer BSM disposed beneath the first active layer ACT1.

The first active layer ACT1 may be disposed on the second buffer layer ABUF, whereas the 1A-th gate electrode layer GAT1a and the 1B-th gate electrode layer GAT1b may be disposed on the lower gate insulating layer GI. The 1A-th electrode layer SD1a and the 1B-th electrode layer SD1b may be disposed on the second upper interlayer insulating layer OILD2 and may be connected to a first electrode region and a second electrode region of the first active layer ACT1, respectively. Meanwhile, although the 1B-th gate electrode layer GAT1b is shown as being connected to the first shield layer BSM by way of example, the present disclosure is not limited thereto.

The first oxide thin-film transistor ODT may include a second active layer ACT2a, a second gate electrode layer OGA1a, a 1C-th electrode layer SD1c, and a 1D-th electrode layer SD1d, which are disposed between the second lower buffer layer OBUF2 and the upper protective layer PPAS. The first oxide thin-film transistor ODT may further include a second shield layer SLM disposed beneath the second active layer ACT2a. The first oxide thin-film transistor ODT may be defined as a driving transistor.

The second active layer ACT2a may be disposed on the second lower buffer layer OBUF2, whereas the second gate electrode layer OGA1a may be disposed on the upper gate insulating layer OGI. The 1C-th electrode layer SD1c and the 1D-th electrode layer SD1d may be disposed on the second upper interlayer insulating layer OILD2 and may be connected to a first electrode region and a second electrode region of the second active layer ACT2a, respectively. Meanwhile, although the 1D-th electrode layer SD1d is shown as being as connected to the second shield layer SLM by way of example, the present disclosure is not limited thereto.

The capacitor CST may include a first electrode layer OGA1b, a first upper insulating layer OILD1, and a second electrode layer OGA2, which are disposed between the upper gate insulating layer OGI and the second upper interlayer insulating layer OILD2.

The first electrode layer OGA1b may be disposed on the upper gate insulating layer (OGI), whereas the first upper insulating layer OILD1 may be disposed on the first electrode layer OGA1b, and the second electrode layer OGA2 may be disposed on the first upper insulating layer OILD1. The first electrode layer OGA1b and the 2A-th gate electrode layer OGA1a are formed on the same layer and, as such, may be regarded as the same material.

The second oxide thin-film transistor OTFT may include a third active layer ACT2b, a third gate electrode layer OGA1c, a 1E-th electrode layer SD1e, and a 1F-th electrode layer SD1f, which are disposed between the second lower buffer layer OBUF2 and the upper protective layer PPAS. The second oxide thin-film transistor OTFT may further include a third shield layer GAT1c disposed beneath the third active layer ACT2b.

The third active layer ACT2b may be disposed on the second lower buffer layer OBUF2, whereas the third gate electrode layer OGA1c may be disposed on the upper gate insulating layer OGI. The 1E-th electrode layer SD1e and the 1F-th electrode layer SD1f may be disposed on the second upper interlayer insulating layer OILD2 and may be connected to a first electrode region and a second electrode region of the third active layer ACT2b, respectively. Meanwhile, although the third drain electrode layer SD1f is shown as being connected to the third shield layer GAT1c by way of example, the present disclosure is not limited thereto.

A first planarization layer PLN1 may be disposed on the upper protective layer PPAS, and a second planarization layer PLN2 may be disposed on the first planarization layer PLN1. A second electrode layer SD2a-SD2b including a 2A-th electrode layer SD2a and a 2B-th electrode layer SD2b may be disposed between the first planarization layer PLN1 and the second planarization layer PLN2. The 2A-th electrode layer SD2a may be connected to the 1C-th electrode layer SD1c of the first oxide thin-film transistor ODT. The 2A-th electrode layer SD2a may be defined as a connection electrode layer configured to connect the 1C-th electrode layer SD1c of the first oxide thin-film transistor ODT to an anode layer AND of the light emitting element OLED.

The 1A-th electrode layer SD1a to the 1F-th electrode layer SD1f described above may be defined as a first source/drain metal layer, whereas the 2A-th electrode layer SD2a and the 2B-th electrode layer SD2b may be defined as a second source/drain metal layer.

The light emitting element OLED may include the anode layer AND, an emission layer EL, and a cathode layer CAT, which are disposed between the second planarization layer PLN2 and a first protective layer EPAS1. The anode layer AND may be disposed on the second planarization layer PLN2, whereas the emission layer EL may be disposed on the anode layer AND, and the cathode layer CAT may be disposed on the emission layer EL. The emission layer EL may be partitioned by a pixel defining layer BNK which is disposed on the second planarization layer PLN2 and has an opening to expose a portion of the anode layer AND. The cathode layer CAT may be disposed to cover the emission layer EL along with the pixel defining layer BNK.

The pixel defining layer BNK may include a spacer SPC. The pixel defining layer BNK and the spacer SPC may be formed of the same material or may be formed of different materials, respectively. The light emitting element OLED may be protected by an encapsulation layer ENC including the first protective layer EPAS1, an intermediate protective layer PCL, and a second protective layer EPAS2. However, the configuration of the encapsulation layer ENC is not limited to the above-described configuration.

On the second protective layer EPAS2 included in the encapsulation layer ENC, a touch screen layer TSP may be disposed. The touch screen layer TSP may include a touch buffer layer SBUF, a touch electrode layer SMET, and a touch protective layer SPAC. The touch electrode layer SMET may be connected to a touch pad included in a pad area based on a touch routing line. The touch screen layer TSP may be selected from transparent electrode materials (e.g., transparent oxides). The touch screen layer TSP may be configured as a mutual capacitance system that detects a variation in capacitance based on the cathode layer CAT included in the light emitting element OLED and the touch electrode layer SMET, and discriminates presence or absence of touch based on the detected capacitance variation, without being limited thereto.

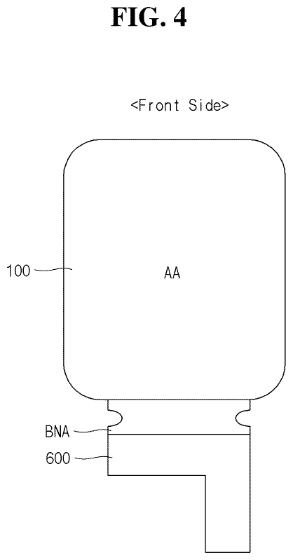

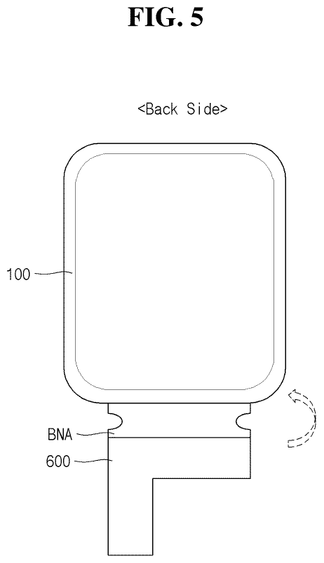

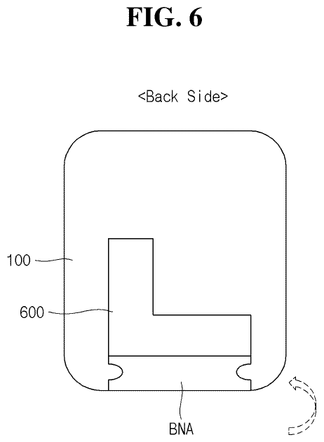

FIG. 4 is an illustrative front view of a display module including the display panel. FIG. 5 is an illustrative rear view of the display module including the display panel. FIG. 6 is an illustrative view showing a state in which a printed circuit board is attached to a back side of the display panel through bending as shown in FIG. 5.

As shown in FIGS. 4 to 6, the display panel 100 may include a printed circuit board 600 configured to receive an electrical signal and a voltage from an external device. Although the printed circuit board 600 is shown as having an L shape by way of example, the shape thereof is not limited to the shown shape. Additionally, although a data driver, other passive components, etc. necessary for operation of the display panel 100 may be disposed on the printed circuit board 600, it is noted that these components are not shown in the drawings. Furthermore, the display panel 100 and the printed circuit board 600 may be defined as a display module.

The active area AA is visible at a front side of the display module including the display panel 100, whereas the active area AA may not be visible at a back side of the display module. An extension part BNA extending from the display panel 100 may be included between the display panel 100 and the printed circuit board 600. The extension part BNA may be used to allow the printed circuit board 600, etc. to transition to the back side of the display panel 100 through a bending procedure (or a bending process). The extension part BNA may be constituted by the substrate SUB shown in FIG. 3 and a part of layers disposed on the substrate SUB. This will be described later.

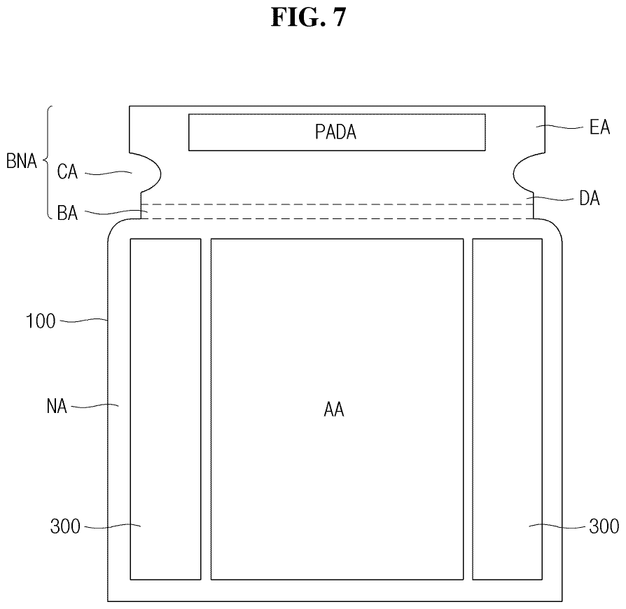

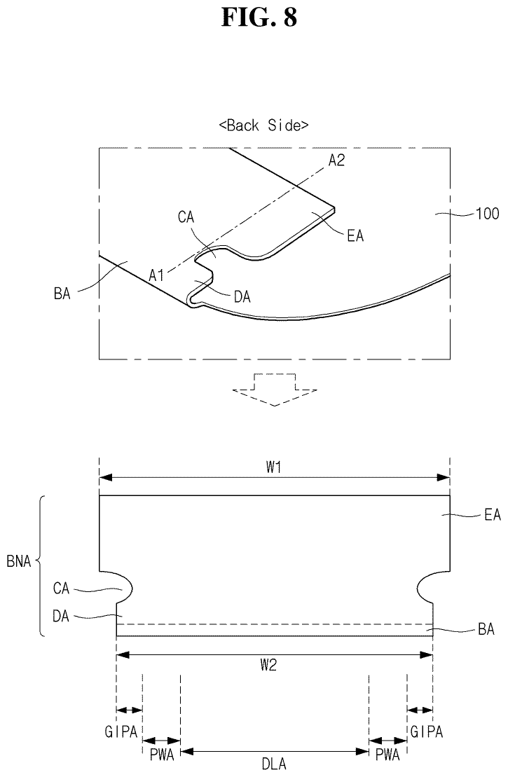

FIG. 7 is a plan view showing the configuration included in the display panel in more detail. FIG. 8 is an illustrative view showing a first example of a state in which a bending area is bent toward the back side of the display panel in FIG. 7, and a configuration of the bending area in more detail. FIG. 9 is an illustrative view showing a second example of a state in which a bending area is bent toward the back side of the display panel in FIG. 7, and a configuration of the bending area in more detail.

As shown in FIG. 7, the display panel 100 may include a pad area PADA, a cutting area CA, a dummy area DA, a bending area BA, an active area AA, a non-active area NA, a gate driver 300, etc. The pad area PADA, the cutting area CA, the dummy area DA, and the bending area BA may be included in the extension part BNA of the display panel 100.

The pad area PADA is an area where pads are disposed to facilitate electrical connection to the printed circuit board 600 shown in FIGS. 7 to 9. The pad area PADA may be disposed adjacent to an upper edge area EA of the display panel 100.

The bending area BA is an area able to be bent to allow the extension part, which includes the pad area PADA, the cutting area CA, and the dummy area DA, to transition to the back side of the display panel 100. The bending area BA may be disposed adjacent to the active area AA and the non-active area NA.

The dummy area DA is an area configured to prevent foreign matter (e.g., resin) from penetrating through a side surface of the bending area BA when the extension part BNA, which includes the pad area PADA and the cutting area CA, is attached to the back side of the display panel 100 in a bent state. Additionally, the dummy area DA may minimize an influence of penetrating foreign matter. The dummy area DA may be locally disposed adjacent to opposite outer edges between the bending area BA and the cutting area CA. A more detailed description of the dummy area DA will be given later.

The cutting area CA is an area configured to form a design facilitating easy connection and coupling of the upper edge area EA including the pad area PADA to other components such as the printed circuit board 600, etc. The cutting area CA may be shaped through cutting to smoothly taper from a main area, which includes the active area AA and the non-active area NA, to the upper edge area EA including the pad area PADA, such that the cutting area CA has a relatively narrow width. Meanwhile, although the cutting area CA has a U shape as an example in FIG. 7, the cutting area CA is not limited to the above-described shape, as apparent from the following description.

As shown in FIG. 8, when viewing the extension part BNA of the display panel 100 from the back side of the display panel 100, a width W2 of the bending area BA may be smaller than a width W1 of the upper edge area EA (an edge area at an end of the extension part as viewed from the display panel). In FIG. 9, when observing the extension part BNA of the display panel 100 from the back side of the display panel 100, a width W3 of the bending area BA may be smaller than the width W1 of the upper edge area EA. The width of the bending area BA (W2 or W3) may be defined to be constant, regardless of the shape of the cutting area CA, or may vary to become wider or narrower in correspondence to the shape of the cutting area CA.

The bending area BA may include a third line area DLA, a second line area PWA, and a first line area GIPA. The third line area DLA may be defined as an area where data lines configured to transmit a data voltage to the sub-pixels disposed in the active area are disposed. The second line area PWA may be defined as an area where voltage lines configured to supply a voltage to the sub-pixels disposed in the active area are disposed. The first line area GIPA may be defined as an area where signal and voltage lines configured to transmit signals and voltages necessary for driving of the gate driver disposed in the non-active area are disposed.

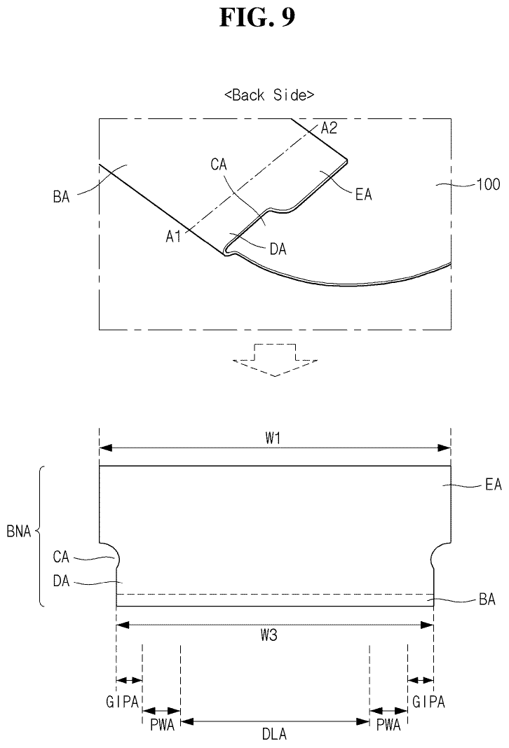

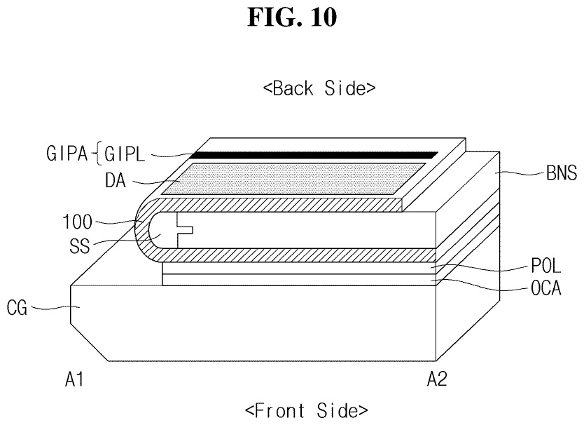

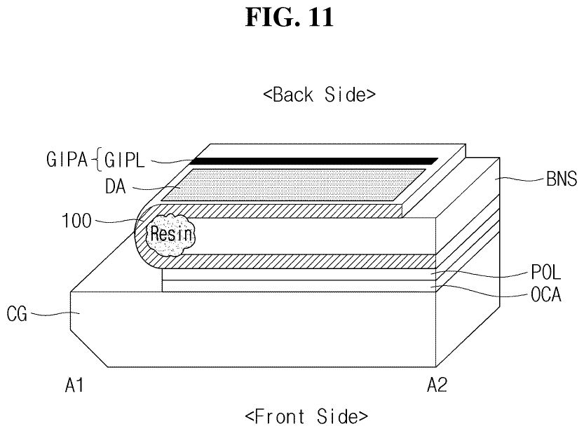

FIG. 10 is an illustrative cross-sectional view showing an A1-A2 area before application of resin in FIGS. 8 and 9. FIG. 11 is an illustrative cross-sectional view of the A1-A2 area after application of resin in FIGS. 8 and 9.

As shown in FIGS. 8 to 11, the extension part BNA of the display panel 100 may be bent in a state of being supported by a structure BNS. Although FIGS. 10 and 11 show an example in which a polarization plate POL, an optical adhesive OCA, and a cover glass CG are attached to the front side of the display panel 100, the present disclosure is not limited thereto.

The extension part BNA of the display panel 100 may be bent while being supported by the structure BNS. A resin may be applied to the bending area BA included in the extension part BNA and a surrounding area thereof to facilitate contact with the structure BNS, other components, or the like.

Meanwhile, even if the extension part BNA of the display panel 100 is bent while being supported by the structure BNS, a gap space SS may be formed between the extension part BNA of the display panel 100 and the structure BNS due to physical characteristics of the bending structure.

In this case, as shown in FIG. 11, foreign matter such as the resin used to facilitate contact between structures may penetrate into the bending area BA through the gap space SS.

The resin may harden from a liquid form to a solid form through a thermal curing process, leading to thermal deformation (shrinkage and expansion) under thermally stressed conditions. The thermal deformation of the resin that has penetrated into the gap space SS may induce stress in the bending area BA and a surrounding area thereof. As a result, cracks in lines (wires) may be formed.

In accordance with an embodiment, the dummy area DA between the cutting area CA and the bending area BA may provide a space configured to prevent penetration of a resin and to store the resin when the resin penetrates into the gap space SS. Additionally, with the inclusion of the dummy area DA, signal and voltage lines GIPL configured to transmit signals and voltages necessary for driving of the gate driver may be arranged to be disposed farther inward than the dummy area DA. As a result, this embodiment may alleviate thermal deformation of the resin that has penetrated into the gap space SS and the resulting stress.

More specifically, the signal and voltage lines GIPL, which transmit signals and voltages necessary for driving of the gate driver in the first line area GIPA, may be relatively free from issues (e.g., line cracks) that may be caused by thermal deformation of the resin and the resulting stress.

To achieve this, the dummy area DA may be disposed farther outward than the signal and voltage lines GIPL. Although FIGS. 10 and 11 only show one side of the display panel 100 at which bending occurs, the dummy area DA may be disposed adjacent to opposite outer edges of the extension part BNA of the display panel 100 (left and right edges defining the width of the extension part). Furthermore, the dummy area DA may be formed to occupy a predetermined area along the signal and voltage lines GIPL. Therefore, the dummy area DA having a rectangular shape shown in FIGS. 10 and 11 should be interpreted as one example.

Hereinafter, a detailed structure configured to achieve the embodiment based on the structure shown in FIG. 8 will be described.

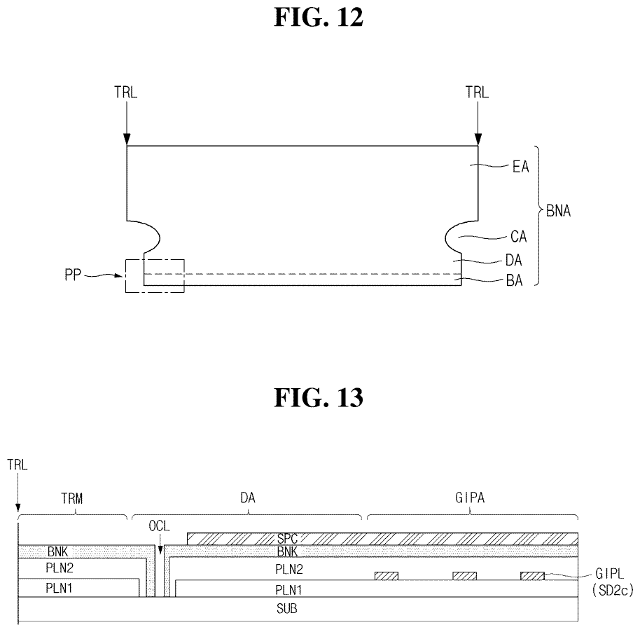

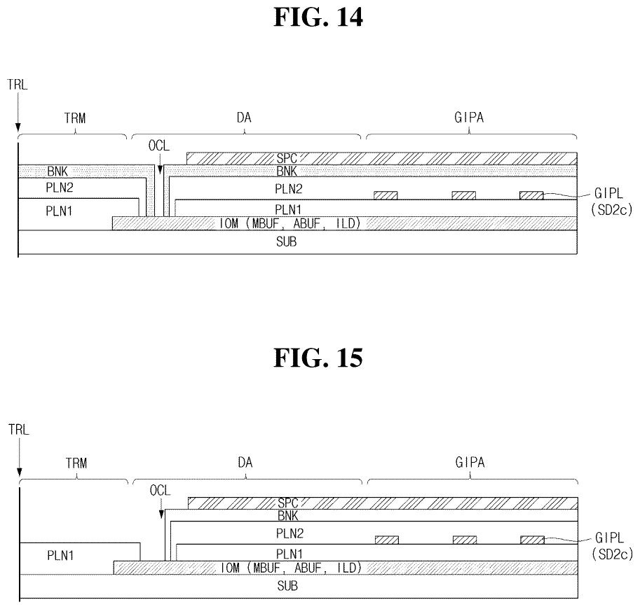

FIG. 12 is an illustrative view showing the extension part of the display panel shown in FIG. 8. FIG. 13 is a cross-sectional view showing an area PP shown in FIG. 12 in accordance with a first embodiment. FIG. 14 is a cross-sectional view showing the area PP shown in FIG. 12 in accordance with a second embodiment. FIG. 15 is a cross-sectional view showing the area PP shown in FIG. 12 in accordance with a third embodiment.

As shown in FIG. 12, the shape of the extension part BNA of the display panel may be defined in accordance with a trimming line TRL defined to allow for a trimming process (cutting process) to be performed therein using a laser. Therefore, the shape of the extension part BNA of the display panel is not limited to those illustrated in FIG. 12 and the drawings previous to FIG. 12.

As shown in FIG. 13, in accordance with the first embodiment, a trimming margin area TRM may be disposed in an area adjacent to the trimming line TRL, and the dummy area DA and the first line area GIPA may be disposed inside the trimming margin area TRM.

The first planarization layer PLN1, the signal and voltage lines GIPL, the second planarization layer PLN2, the pixel defining layer BNK, and the spacer SPC, which are disposed on the substrate SUB, may be disposed in the dummy area DA and the first line area GIPA. In contrast, the first planarization layer PLN1, the second planarization layer PLN2, and the pixel defining layer BNK, which are disposed on the substrate SUB, may be disposed in the trimming margin area TRM. Meanwhile, the signal and voltage lines GIPL disposed in the first line area GIPA may be formed on the same layer as that of the 2C-th electrode layer SD2c included in the second electrode layer as shown in FIG. 3, using the same material as that of the 2C-th electrode layer SD2c, without being limited thereto.

Between the trimming margin area TRM and the dummy area DA, an organic layer disconnection part OCL may be disposed. The organic layer disconnection part OCL may serve to separate the first planarization layer PLN1, the second planarization layer PLN2, and the pixel defining layer BNK, which are commonly included in the trimming margin area TRM, the dummy area DA, and the first line area GIPA.

By separating the layers included in the trimming margin area TRM and the dummy area DA, as described above, the ability to prevent and minimize introduction of foreign matter and moisture may be enhanced. As a result, this embodiment may not only enhance electrical and structural stability and reliability of the resultant device, but also may increase the lifespan of the device.

As illustrated in FIG. 14, in accordance with the second embodiment, an inorganic layer IOM, the first planarization layer PLN1, the signal and voltage lines GIPL, the second planarization layer PLN2, the pixel defining layer BNK, and the spacer SPC, which are disposed on the substrate SUB, may be disposed in the dummy area DA and the first line area GIPA. In contrast, the inorganic layer IOM, the first planarization layer PLN1, the second planarization layer PLN2, and the pixel defining layer BNK, which are disposed on the substrate SUB, may be disposed in the trimming margin area TRM.

In accordance with the second embodiment, the inorganic layer IOM may include the first buffer layer MBUF, the second buffer layer ABUF, and the lower interlayer insulating layer ILD as shown in FIG. 3, without being limited thereto. Furthermore, in accordance with the second embodiment, the organic layer disconnection part OCL disconnects only organic layers such as the first planarization layer PLN1, the second planarization layer PLN2, the pixel defining layer BNK, etc. Accordingly, the inorganic film layer IOM may extend to the trimming margin area TRM along the dummy area DA and the first line area GIPA, without being disconnected. Meanwhile, the inorganic layer IOM may extend only up to an area adjacent to the trimming line TRL beyond the dummy area DA in order to ensure that the trimming process (cutting process) using a laser may be performed smoothly.

As shown in FIG. 15, in accordance with the third embodiment, the inorganic film layer IOM, the first planarization layer PLN1, the signal and voltage lines GIPL, the second planarization layer PLN2, the pixel defining layer BNK, and the spacer SPC, which are disposed on the substrate SUB, may be disposed in the dummy area DA and the first line area GIPA. In contrast, the inorganic layer IOM and the first planarization layer PLN1 disposed on the substrate SUB may be disposed in the trimming margin area TRM.

In accordance with the third embodiment, since only the first planarization layer PLN1, which is a single organic layer, is disposed in the trimming margin area TRM, the potential for formation and residue of organic byproducts during the trimming process using a laser may be minimized. Additionally, between the trimming margin area TRM and the dummy area DA, an organic film step (with the trimming margin area having a lower interlayer structure than the dummy area) is formed. Accordingly, it may be possible to provide a space capable of preventing penetration of foreign matter such as a resin or the like and storing penetrating foreign matter when the foreign matter penetrates.

As apparent from the above description, the present disclosure has an effect of preventing a resin, which is used in a display module having a configuration in which an extension part of a display panel is bent to be folded toward a back side of the display panel, from penetrating a gap space formed at the extension part of the display panel. Additionally, the present disclosure has an effect of minimizing a problem (for example, line cracks) possibly occurring due to thermal deformation of the resin and the resulting stress when penetration of the resin has occurred. Additionally, the present disclosure has effects of not only enhancing electrical and structural stability and reliability of the resultant device, but also increasing the lifespan of the device by preventing or minimizing introduction of foreign matter or moisture into the gap space formed at the extension part of the display panel.

Effects according to the exemplary embodiments of the disclosure are not limited to the above-illustrated contents, and more various effects may be included in the specification.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A display device comprising:
a display panel comprising an active area configured to display an image;
an extension part extending from a substrate comprised in the display panel;
a bending area comprised in the extension part and configured to be bent to allow the extension part to be disposed at a back side of the display panel;
a pad area comprised in the extension part and configured to facilitate connection of the display device to an external circuit board;
a line area disposed in the pad area, the bending area, and the active area, the line area comprising lines configured to transmit a signal and a voltage applied through the pad area; and
a dummy area positioned adjacent to the bending area and disposed outside the line area.

2. The display device according to claim 1, wherein the dummy area is locally disposed adjacent to outer edges of the extension part.

3. The display device according to claim 1, wherein the extension part is bent based on a structure such that the extension part is disposed at the back side of the display panel and includes a gap space formed between the bending area and the structure.

4. The display device according to claim 1, wherein:
the extension part comprises a trimming line area defined to allow for a trimming process to be performed therein and disposed outside the dummy area; and
the trimming line area and the dummy area have different interlayer structures.

5. The display device according to claim 4, wherein the trimming line area and the dummy area comprise at least one organic layer in common.

6. The display device according to claim 5, wherein the at least one organic layer is separated by an organic layer disconnection part disposed between the trimming line area and the dummy area.

7. The display device according to claim 5, wherein the dummy area and the line area commonly comprise:
the substrate disposed at the extension part;
a first planarization layer disposed on the substrate;
a second planarization layer disposed on the first planarization layer; and
a pixel defining layer disposed on the second planarization layer.

8. The display device according to claim 7, wherein the trimming line area has a lower interlayer structure than the dummy area.

9. The display device according to claim 8, wherein the trimming line area includes the first planarization layer disposed on the substrate.

10. The display device according to claim 8, wherein the trimming line area further includes an inorganic layer extending from the dummy area disposed between the first planarization layer and the substrate.

11. A method of manufacturing a display device, the method comprising:
attaching a circuit board to the pad area comprised in the extension part of the display panel according to claim 1;
bending the bending area to allow the extension part comprising the pad area, the line area, and the dummy area to be disposed at the back side of the display panel; and
coating the bending area and a surrounding area surrounding the bending area with a resin.

12. The method according to claim 11, wherein the dummy area is locally disposed adjacent to outer edges of the extension part.
